(19) United States
(12) Patent Application Publication
(10) Pub. No.: US 2025/0378888 A1
(43) Pub. Date: Dec. 11, 2025

(54) MANAGING WARMUP OPERATIONS IN A MEMORY DEVICE

(71) Applicant: Yangtze Memory Technologies Co., Ltd., Wuhan (CN)

(72) Inventors: Lei JIA, Wuhan (CN); Shu XIE, Wuhan (CN); Lin MIAO, Wuhan (CN)

(21) Appl. No.: 18/791,351

(22) Filed: Jul. 31, 2024

Related U.S. Application Data
(63) Continuation of application No. PCT/CN2024/097509, filed on Jun. 5, 2024.

(51) Int. Cl. G11C 16/26; G11C 16/08; G11C 16/32

(52) U.S. Cl. CPC G11C 16/26; G11C 16/08; G11C 16/32

(57) ABSTRACT

Methods, devices, and systems for managing warmup operations in memory devices are provided. In one aspect, an input/output (I/O) interface of a memory device can be configured to receive a first address of first data to be read, receive warmup information that indicates a warmup period before reading the first data, and determine, based on the first address and the warmup information, a second address of second data to be read during the warmup period before reading the first data.

### CROSS-REFERENCE TO RELATED APPLICATIONS

This application is a continuation of International Application No. PCT/CN2024/097509, filed on Jun. 5, 2024, the disclosure of which is hereby incorporated by reference in its entirety.

### TECHNICAL FIELD

The present disclosure generally relates to memory devices and memory systems, and in particular, to managing warmup operations in memory devices.

### BACKGROUND

Flash memory is a low-cost, high-density, nonvolatile solid-state storage medium that can be electrically erased and reprogrammed. Flash memory includes NOR flash memory and NAND flash memory. Various operations can be performed by flash memory, for example, program (write) and erase operations, to change the threshold voltage of each memory cell to a respective level. For NAND flash memory, an erase operation can be performed at the block level, a program operation can be performed at the page level, and a read operation can be performed at the page level.

### SUMMARY

The present disclosure involves methods, apparatuses, and systems for managing warmup operations in memory devices. In one example, an input/output (I/O) interface of a memory device can be configured to receive a first address of first data to be read, receive warmup information that indicates a warmup period before reading the first data, and determine, based on the first address and the warmup information, a second address of second data to be read during the warmup period before reading the first data. The warmup operation can be performed by reading the second data during the warmup period, before reading the first data.

In some implementations, the I/O interface includes an address shifter and a first frequency divider coupled to the address shifter. The address shifter is configured to determine the first address less a quantity of warmup cycles as the second address, and send the second address to the first frequency divider.

In some implementations, the address shifter is configured to, in response to determining that the first address less the quantity of warmup cycles is a negative value, account for the negative value in determining the second address.

In some implementations, the I/O interface receives a first clock signal. The first frequency divider is configured to generate a second clock signal having one-fourth a frequency of the first clock signal.

In some implementations, the first data and the second data are read from a first-in-first-out (FIFO) cache of the memory device.

In some implementations, the address shifter is configured to account for the negative value in determining the second address by sending a control signal to the first frequency divider. The control signal is configured to instruct an output pointer of the FIFO cache to skip a first rising edge of the second clock signal during the warmup period.

In some implementations, the I/O interface includes a second frequency divider configured to generate a third clock signal having half the frequency of the first clock signal, and a third frequency divider configured to generate a fourth clock signal having one-eighth the frequency of the first clock signal.

In some implementations, the I/O interface is configured to, in response to receiving a read command to read the first data, reset a data path of the I/O interface during a first pulse, read data based on a fourth least significant bit of the second address during a second pulse, read data based on a third least significant bit of the second address during a third pulse, and read data based on a second least significant bit of the second address during a fourth pulse.

In some implementations, the I/O interface is configured to, in response to receiving, a read resume command to read the first data after a read pause, reset a data path of the I/O interface during a first pulse, read data based on a fourth least significant bit of the second address during a second pulse, read data based on a third least significant bit of the second address during a third pulse, and read data based on a second least significant bit of the second address during a fourth pulse.

In some implementations, the I/O interface is configured to output the second data during the warmup period, output the first data after the warmup period.

One aspect of the present disclosure provides a memory device. The memory device, including a memory cell array including memory cells, and peripheral circuits coupled to the memory cell array. The peripheral circuits include an input/output (I/O) interface. The I/O interface is configured to receive a first address of first data to be read, receive warmup information that indicates a warmup period before reading the first data, and determine, based on the first address and the warmup information, a second address of second data to be read during the warmup period before reading the first data.

In some implementations, the I/O interface includes an address shifter and a first frequency divider coupled to the address shifter. The address shifter is configured to determine the first address less a quantity of warmup cycles as the second address, and send the second address to the first frequency divider.

In some implementations, the address shifter is configured to, in response to determining that the first address less the quantity of warmup cycles is a negative value, account for the negative value in determining the second address.

In some implementations, the peripheral circuits include a first-in-first-out (FIFO) cache. the first data and the second data are read from the FIFO cache.

In some implementations, the I/O interface receives a first clock signal. The first frequency divider is configured to generate a second clock signal having one-fourth a frequency of the first clock signal. The address shifter is configured to account for the negative value in determining the second address by sending a control signal to the first frequency divider. The control signal is configured to instruct an output pointer of the FIFO cache to skip a first rising edge of the second clock signal during the warmup period.

In some implementations, the peripheral circuits are configured to read the second data during the warmup period, and read the first data after the warmup period.

In some implementations, the memory device includes a NAND memory device.

One aspect of the present disclosure provides a memory system. The memory system includes a memory controller and a memory device coupled to the memory controller. The memory controller is configured to send a read command to read first data, a first address of the first data and warmup information that indicates a warmup period before reading the first data. The memory device includes a memory cell array including memory cells, and a peripheral circuit including an input/output (I/O) interface. The I/O interface is configured to receive the read command, the first address and the warmup information, and determine, based on the first address and the warmup information, a second address of second data to be read during the warmup period before reading the first data.

In some implementations, determining the second address includes determining the first address less a quantity of warmup cycles as the second address.

In some implementations, the peripheral circuit is configured to read the second data during the warmup period, and read the first data array after the warmup period.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates a block diagram of an example system having a memory device, according to some aspects of the present disclosure.

FIGS. 2A-2B illustrate example storage products, according to some aspects of the present disclosure.

FIG. 3 illustrates a schematic diagram of an example memory device including peripheral circuits, according to some aspects of the present disclosure.

FIG. 4 illustrates some example peripheral circuits, according to some aspects of the present disclosure.

FIG. 5 illustrates a schematic timing diagram of an example data output process, according to some aspects of the present disclosure.

FIG. 6 illustrates some example circuits in the I/O interface, according to some aspects of the present disclosure.

FIG. 7 illustrates a schematic diagram of an example process of generating shifted column address based on column address of output data and quantity of warmup cycles, according to some aspects of the present disclosure.

FIG. 8 illustrates an example look-up table of shifted address according to the address of the output data and the quantity of warmup cycles, according to some aspects of the present disclosure.

FIG. 9 illustrates a flow chart of an example process of fetching data from an output buffer, according to some aspects of the present disclosure.

FIG. 10 illustrates an example method of reading data from a memory system, according to some aspects of the present disclosure.

FIG. 11 illustrates a flow chart of an example process of performing a read operation that includes warmup cycles, according to some aspects of the present disclosure.

FIG. 12 illustrates a schematic timing diagram of example read pause and resume, according to some aspects of the present disclosure.

Like reference numbers and designations in the various drawings indicate like elements.

### DETAILED DESCRIPTION

This specification relates to memory devices, memory systems, and methods for managing warmup operations in NAND flash memory. In Dynamic Random-Access Memory (DRAM) memory, preamble/post-amble mechanisms are provided for input/output (I/O) interfaces to ensure accurate data transmission. For example, extra transitions for clock signals, such as write clock (WCK) and read data strobe (RDQS) signals, are provided before and after clock signals for valid data transmission. Different from DRAM I/O interfaces, preamble/postamble mechanisms are generally not provided for NAND I/O interfaces for consideration of lower power consumption. To enhance the stability and accuracy in data transmission in NAND I/O interfaces, especially under high-speed data transmission in NAND I/O interfaces (e.g., 800 Mbps or higher), warmup cycles are provided at the beginning of the data input and/or output in NAND flash memory.

In some cases, warmup operations during the warmup cycles are performed by using a clock gating method. Specifically, after entering read/write mode, clock path for read/write operations are locked during warmup cycles. After completing warmup cycles, a global warmup control sends control signals to switch on clock paths for each data line (DQ) or data strobe (DQS) signal. The control signals from the global warmup control need to reach each DQ within one cycle so as to trigger the next operation, and each DQ may need to switch on its clock path precisely within half a cycle. Untimely or delayed switching of the clock path may create glitches in the clock path, leading to abnormal read and/or write operations. However, as the speed of NAND I/O interfaces continues to increase (e.g., exceeding 3.6 Gbps), the time margin to switch on clock paths becomes thinner (e.g., less than 100 ps). It is therefore challenging to switch on clock paths within half a cycle, thus making it difficult to perform warmup operations using the clock gating method for high-speed NAND I/O interfaces.

The present disclosure provides techniques to perform warmup operations in NAND flash memory by shifting read addresses (e.g., address of data to be output from the I/O interface). In some implementations, the NAND I/O interface can include an address shifter configured to determine a shifted read address based on the original read address (e.g., address of data that a host intends to read, for example, as indicated by a read command) and configuration information on the warmup cycles (e.g., a quantity of warmup cycles provided at the beginning of the data output). For example, the shifted read address can be determined as the original read address less the quantity of warmup cycles. As such, when the data output starts with the warmup cycles, data lines of the I/O interface can output dummy data (e.g., data not intended by the host to be read, also referred to as warmup data) starting from the shifted read address. After the warmup cycles are completed, data lines of the I/O interface can output data, starting precisely from the original read address.

In some implementations, the described techniques can achieve one or more technical effects. For example, warmup operations by shifting read addresses do not require switching on clock paths within a certain time margin, and therefore are more compatible with high-speed I/O interfaces. In addition, compared to warmup operations by using the clock gating method, where the clock paths are locked during warmup cycles and therefore no data are transmitted on the data lines during the warmup cycles, in warmup operations by shifting read addresses, dummy data are transmitted on the data lines during the warmup cycles. As such, more circuits in the I/O interface and in other peripheral circuits of the NAND flash memory are warmed up by actively working during the warmup cycles, making the warmup operations more comprehensive and effective. Furthermore, the described techniques do not require adding logic control on the high-speed clock path, thereby clock noise can be reduced. Additionally, the described techniques do not rely on high-speed circuits, and thus lower-speed devices with smaller leakage can be used to implement the described techniques. In some implementations, idle power consumption can thereby be reduced, and layout floorplan of the NAND flash memory can be simplified. In some implementations, additional or different technical effects can be achieved.

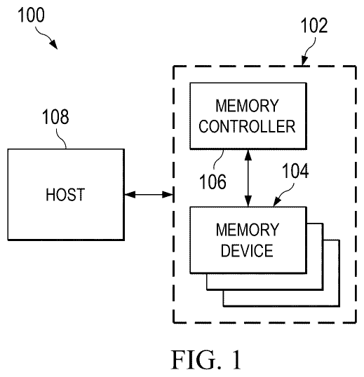

FIG. 1 illustrates a block diagram of an example system 100 having a memory device, according to some aspects of the present disclosure. The system 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, the system 100 can include a host 108 and a memory system 102 having one or more memory devices 104 and a memory controller 106. The host 108 can include one or more processors of an electronic device. The processor can be a central processing unit (CPU), or a system-on-chip (SoC), such as an application processor (AP). The host 108 can be configured to send or receive data and commands to or from the memory systems 102.

The memory device 104 can be any memory device disclosed in the present disclosure, such as a NAND flash memory device. It is noted that the NAND flash is only one example of memory device for illustrative purposes. It can include any suitable solid-state, non-volatile memory, e.g., NOR flash, Ferroelectric RAM (FeRAM), Phase-change memory (PCM), Magneto-resistive random-access memory (MRAM), Spin-transfer torque magnetic random-access memory (STT-RAM), or Resistive random-access memory (RRAM), etc. In some implementations, memory device 104 includes a three-dimensional (3D) NAND flash memory device.

The memory controller 106 can be implemented by microprocessors, microcontrollers (a.k.a. microcontroller units (MCUs)), digital signal processors (DSPs), application-specific integrated circuits (ASICs), field-programmable gate arrays (FPGAs), programmable logic devices (PLDs), state machines, gated logic, discrete hardware circuits, and other suitable hardware, firmware, and/or software configured to perform the various functions described below in detail.

The memory controller 106 is coupled to the memory device 104 and to the host 108, and is configured to control the memory device 104, according to some implementations. The memory controller 106 can manage the data stored in the memory device 104 and can communicate with the host 108. In some implementations, the memory controller 106 is designed for operating in a low duty-cycle environment, such as secure digital (SD) cards, compact flash (CF) cards, universal serial bus (USB) flash drives, or other media for use in electronic devices, such as personal computers, digital cameras, mobile phones, etc. In some implementations, memory controller 106 is designed for operating in a high duty-cycle environment solid state drives (SSDs) or embedded multi-media-cards (eMMCs) used as data storage for mobile devices, such as smartphones, tablets, laptop computers, etc., and enterprise storage arrays. The memory controller 106 can be configured to control operations of the memory device 104, such as read, erase, and program operations. The memory controller 106 can also be configured to manage various functions with respect to the data stored or to be stored in the memory device 104 including, but not limited to bad-block management, garbage collection, logical-to-physical address conversion, logical-to-physical mapping management, wear leveling, etc. In some implementations, the memory controller 106 is further configured to process error correction codes (ECCs) with respect to the data read from or written to the memory device 104. Any other suitable functions can be performed by the memory controller 106 as well, for example, formatting the memory device 104.

The memory controller 106 can communicate with an external device (e.g., the host 108) according to a particular communication protocol. For example, the memory controller 106 can communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc. The memory controller 106 is configured to receive and transmit a command to and from the host 108, and execute or perform multiple functions and operations provided in the present disclosure, which will be described later.

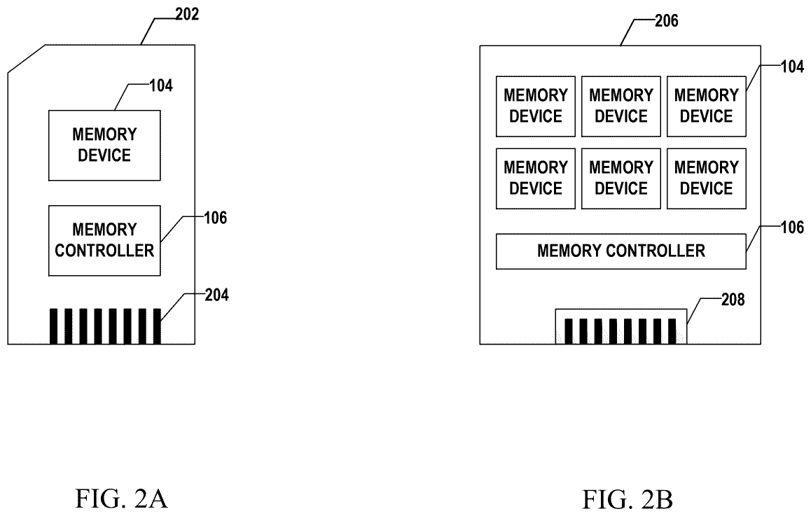

The memory controller 106 and the one or more memory devices 104 can be integrated into various types of storage devices. For example, the memory controller 106 and the one or more memory devices 104 can be packaged in a universal flash storage (UFS) package or an eMMC package. In one example as shown in FIG. 2A, the memory controller 106 and a single memory device 104 can be integrated into a memory card 202. The memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 202 can further include a memory card connector 204 coupling the memory card 202 with a host (e.g., host 108 in FIG. 1). In another example as shown in FIG. 2B, the memory controller 106 and multiple memory devices 104 can be integrated into an SSD 206. The SSD 206 can further include an SSD connector 208 that couples the SSD 206 with a host (e.g., host 108 in FIG. 1). In some implementations, the storage capacity and/or the operation speed of the SSD 206 is greater than those of the memory card 202.

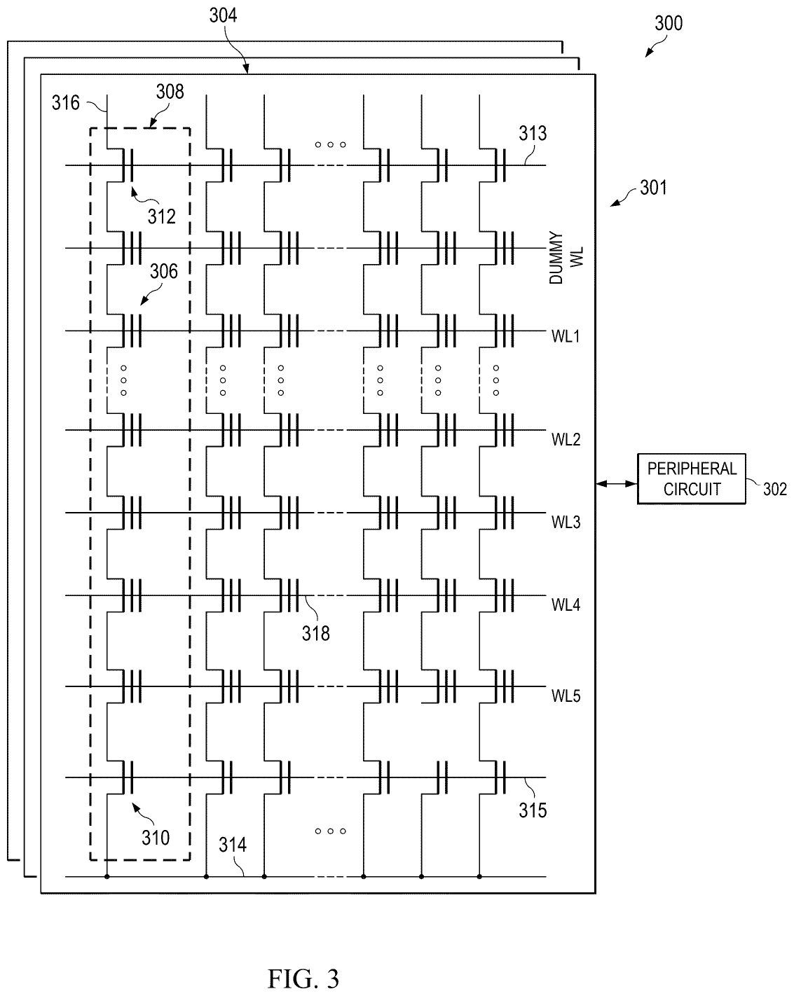

FIG. 3 illustrates a schematic diagram of an example memory device 300 including peripheral circuits, according to some aspects of the present disclosure. The memory device 300 can include a memory cell array 301 and peripheral circuits 302 coupled to the memory cell array 301. The memory cell array 301 can be a NAND flash memory cell array in which memory cells 306 are provided in the form of an array of NAND memory strings 308 each extending vertically above a substrate (not shown in FIG. 3). In some implementations, each NAND memory string 308 includes a plurality of memory cells 306 coupled in series and stacked vertically. Each memory cell 306 can hold a continuous, analog value, such as an electrical voltage or charge that depends on the number of electrons trapped within a storage layer of the memory cell 306. The logic state (i.e., data) of each memory cell 306 in a memory block 304 can be determined based on the threshold voltage Vth of the memory cell 306. Each memory cell 306 can be a floating gate type memory cell including a floating-gate transistor, or a charge trap type memory cell including a charge-trap transistor.

In some implementations, each memory cell 306 is a single-level cell (SLC) with two possible memory states that can store one bit of data. For example, the first memory state “0” can correspond to a first range of voltages, and the second memory state “1” can correspond to a second range of voltages. In some implementations, each memory cell 306 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state.

As shown in FIG. 3, each NAND memory string 308 can include a source select gate (SSG) 310 at its source end and a drain select gate (DSG) 312 at its drain end. The SSG 310 and the DSG 312 can be configured to activate selected NAND memory strings 308 (columns of the array) during read and program operations. In some implementations, the sources of NAND memory strings 308 in the same memory block 304 are coupled through a same source line (SL) 314, e.g., a common SL. In other words, NAND memory strings 308 in the same memory block 304 have an array common source (ACS), according to some implementations. The DSG 312 of each NAND memory string 308 is coupled to a respective bit line 316 from which data can be read or written via an output bus (not shown), according to some implementations. In some implementations, each NAND memory string 308 is configured to be selected or deselected by applying a select voltage (e.g., above the threshold voltage of the transistor having the DSG 312) or a deselect voltage (e.g., 0 V) to the respective DSG 312 through one or more DSG lines 313, and/or by applying a select voltage (e.g., above the threshold voltage of the transistor having the SSG 310) or a deselect voltage (e.g., 0 V) to the respective SSG 310 through one or more SSG lines 315.

As shown in FIG. 3, NAND memory strings 308 can be organized into multiple memory blocks 304, each of which can have a common SL 314 coupled to the ACS. In some implementations, each memory block 304 can serve as a basic data unit for erase operations, such that memory cells 306 on the same memory block 304 are erased at the same time. To erase memory cells 306 in a selected memory block 304, the SL 314 coupled to the selected memory block 304 and unselected memory blocks in the same plane can be biased with an erase voltage. For example, the erase voltage can be a high positive voltage (e.g., 20 V or more). In some implementations, an erase operation can be performed at a half-block level, a quarter-block level, or a level having any suitable number of memory blocks or fractions of a memory block.

The memory cells 306 of adjacent NAND memory strings 308 can be coupled through word lines 318. The word line 318 can select which row of memory cells 306 is affected by read and program operations. Each word line 318 can include a gate line coupled to a plurality of control gates (gate electrodes) of a plurality of memory cells 306. Example word lines shown in FIG. 3 are between one or more DSG lines 313 and one or more SSG lines 315.

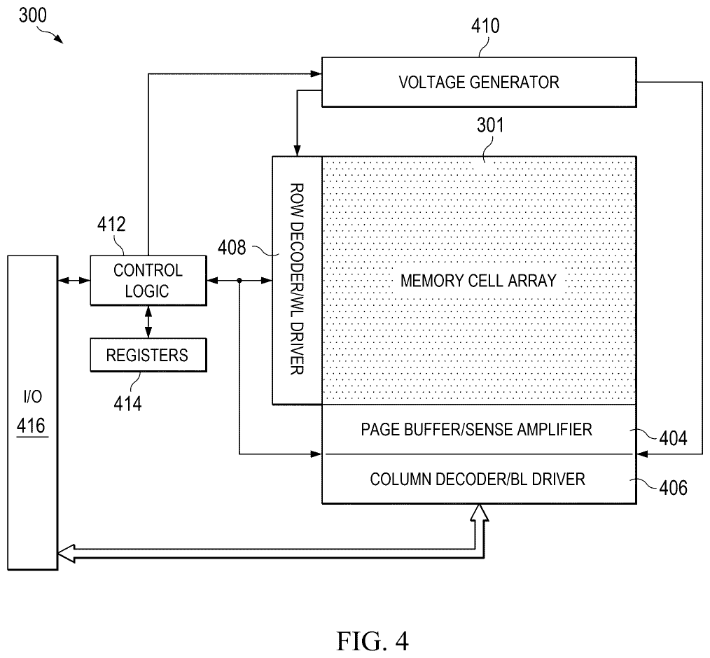

FIG. 4 illustrates some example peripheral circuits 302, according to some aspects of the present disclosure. The peripheral circuits 302 can be coupled to the memory cell array 301 through bit lines 316, word lines 318, SLs 314, SSG lines 315, and DSG lines 313. The peripheral circuits 302 can include any suitable analog, digital, and mixed-signal circuits for facilitating the operations of the memory cell array 301 by applying and sensing voltage signals and/or current signals to and from each target memory cell 306 through bit lines 316, word lines 318, SLs 314, SSG lines 315, and DSG lines 313. The peripheral circuits 302 can include various types of peripheral circuits formed using metal-oxide-semiconductor (MOS) technologies. The example peripheral circuits 302 include a page buffer/sense amplifier 404, a column decoder/bit line driver 406, a row decoder/word line driver 408, a voltage generator 410, control logic 412, registers 414, an input/output (I/O) interface 416, and a data bus. In some examples, additional peripheral circuits not shown in FIG. 4 may be included as well.

The page buffer/sense amplifier 404 can be configured to read and program (write) data from and to memory cell array 301 according to the control signals from control logic 412. In another example, the page buffer/sense amplifier 404 may perform program verify operations to ensure that the data have been properly programmed into memory cells 306 coupled to selected word lines 418. In still another example, the page buffer/sense amplifier 404 may also sense the low power signals from the bit line 316 that represents a data bit stored in memory cell 306, and amplify the small voltage swing to recognizable logic levels in a read operation. The column decoder/bit line driver 406 can be configured to be controlled by the control logic 412 and select one or more NAND memory strings 308 by applying bit line voltages generated from the voltage generator 410.

The row decoder/word line driver 408 can be configured to be controlled by the control logic 412 and select/deselect memory blocks 304 of the memory cell array 301 and select/deselect word lines 418 of the memory block 304. The row decoder/word line driver 408 can be further configured to drive word lines 418 using word line voltages generated from the voltage generator 410. In some implementations, the row decoder/word line driver 408 can also select/deselect and drive SSG lines 415 and DSG lines 413. As described below in detail, the row decoder/word line driver 408 is configured to apply a program voltage to selected word line 418 in a program operation on memory cell 306 coupled to selected word line 418.

The voltage generator 410 can be configured to be controlled by the control logic 412 and generate the word line voltages (e.g., read voltage, program voltage, pass voltage, local voltage, verify voltage, etc.), bit line voltages, and source line voltages to be supplied to the memory cell array 301.

The control logic 412 can be coupled to each peripheral circuit described above and configured to control operations of each peripheral circuit. The registers 414 can be coupled to the control logic 412 and include status registers, command registers, and address registers for storing status information, command operation codes (OP codes), and command addresses for controlling the operations of each peripheral circuit.

The I/O interface 416 can be coupled to the control logic 412 and act as a control buffer to buffer and relay control commands received from a memory controller to the control logic 412 and status information received from the control logic 412 to the memory controller. The I/O interface 416 can also be coupled to the column decoder/bit line driver 406 via a data bus, and act as a data input/output (I/O) interface and a data buffer to buffer and relay data to and from the memory cell array 301.

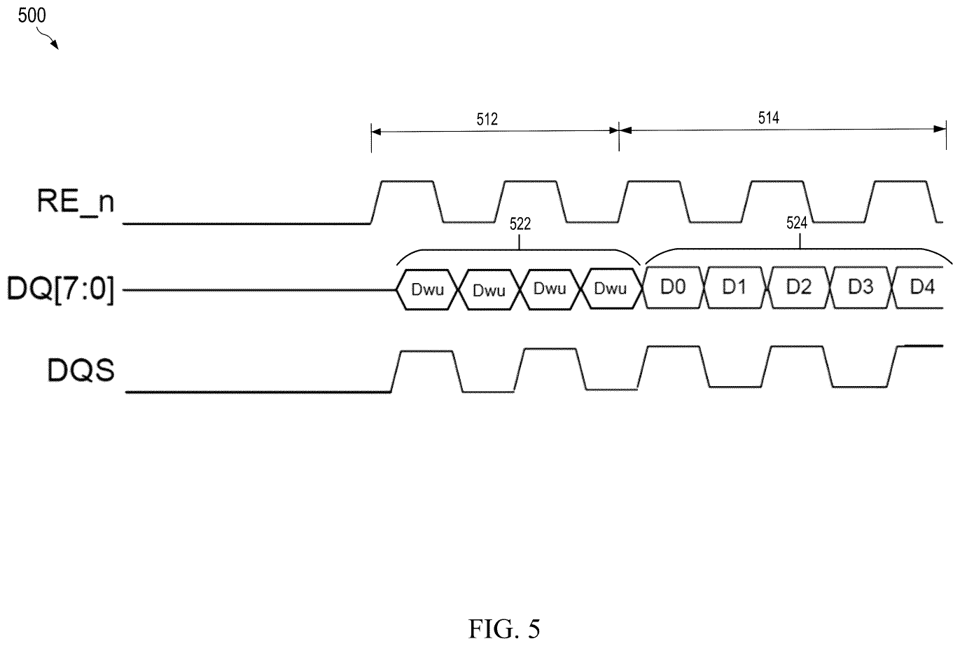

FIG. 5 illustrates a schematic timing diagram of an example data output process 500, according to some aspects of the present disclosure. The data output process 500 can include command signals such as a read enable signal (RE_n), a data strobe signal (DQS) corresponding to RE_n, and a data line signal DQ[7:0].

To support high-speed operation, the I/O interface 416 can support warmup cycles before outputting data from the memory device 300, or inputting data into the memory device 300. In some implementations, the data output process 500 can include warmup cycles 512 and data output cycles 514 following the warmup cycles 512. During the data output cycles 514, the I/O interface 416 outputs output data 524 (e.g., including D0, D1, D2, D3, D4, . . . ) as requested by the memory controller by one or more read commands. To ensure data integrity and accuracy during data output cycles 514, warmup cycles 512 are provided before data output cycles 514. In some implementations, the warmup cycles are provided by providing extra RE_n transitions and corresponding DQS transitions at the beginning of the data output process 500. The extra RE_n and DQS transitions are associated with warmup data 522. For example, during the warmup cycles 512, DQ[7:0] can output warmup data 522 in response to both rising edges and falling edges of RE_n and DQS signals. In some implementations, the warmup data 522 can be different from output data 524, e.g., in front of the output data 524 in a First-In-First-Out (FIFO) cache. In some other implementations, the warmup data 522 can be the same as a part of the output data 524, e.g., a beginning portion of the output data 524.

In some implementations, the data output process 500 can include, for example, one, two or four warmup cycles 512. For example, as shown in FIG. 5, the data output process 500 includes two warmup cycles 512 before data output cycles 514. Each warmup cycle 512 includes a full RE_n cycle (including both a rising edge of a falling edge for RE_n) and a full corresponding DQS cycle (including both a rising edge and a falling edge for DQS). For example, in case that data are transmitted at both the rising edge and the falling edge for DQS, two bits of warmup data 522 can be output through each pin of DQ[7:0] during a warmup cycle 512. In some implementations, the memory controller can send warmup information (e.g., FA 02h Set Feature of NV-DDR2, NV-DDR3, NV-LPDDR4 Configuration) to the I/O interface 416. The warmup information can indicate a quantity of warmup cycles 512, among other configuration information about warmup cycles 512, e.g., whether warmup cycles 512 are enabled for data input process and/or data output process, the quantity of warmup cycles provided for data input process.

In some implementations, when the memory controller pauses and then resumes a data output process, the resumed data output process can also include warmup cycles 512 before continuing to output data after the pause. In some implementations, data input process can also include warmup cycles. The quantity of warmup cycles for data input process and data output process 500 can be configured as same or different values. Warmup cycles are active when the selected data interface is NV-DDR2, NV-DDR3 or NV-LPDDR4 and warmup cycles are enabled in the NV-DDR2/NV-DDR3/NV-LPDDR4 Configuration feature. For NV-DDR2, it is recommended that the NV-DDR2/NV-DDR3/NV-LPDDR4 Configuration feature be configured using the SDR data interface. If warmup cycles are enabled while the NV-DDR2, NV-DDR3 or NV-LPDDR4 interface is active, warmup cycles shall be used for all subsequent commands after the Set Features is complete.

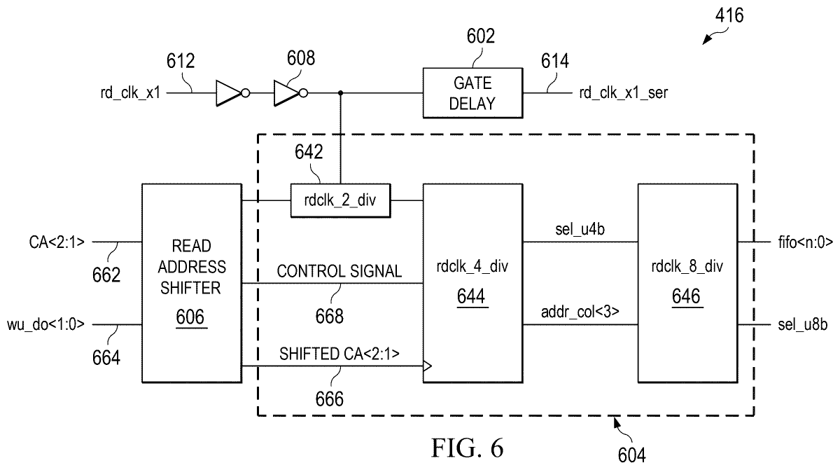

FIG. 6 illustrates some example circuits in the I/O interface 416, according to some aspects of the present disclosure. Example circuits in the I/O interface 416 can include a gate delay circuit 602, a frequency divider circuit 604, a read address shifter 606, and one or more inverters 608. The I/O interface 416 may include other circuits such as a read clock generator, a write clock generator, a serial-parallel converter, etc.

In some implementations, the gate delay circuit 602 can receive a first read clock signal 612 (rd_clk_x1) and generate a second read clock signal 614 (rd_clk_x1_ser). For example, the first read clock signal 612 can be RE_n signal of FIG. 5. The second read clock signal 614 can be DQS signal of FIG. 4, with the same frequency as the first read clock signal 612 and delayed phase position as compared to the first read clock signal 612. In some cases, a memory cell array (e.g., the memory cell array 301 of FIG. 3) outputs data on a relatively low frequency, e.g. lower than a frequency of data output by the I/O interface. Another frequency dividing circuit (not shown in FIG. 6) can generate a low-frequency signal based on the first read clock signal 612 to control data output from the memory cell array. For example, the low-frequency signal, together with the second read clock signal 612, can be received by a sterilizer that controls the serial data output from the memory cell array to the FIFO cache. The FIFO cache can be used as an intermediary storage that compensates for the speed difference between the memory device and the memory controller. In some implementations, the FIFO cache in a NAND interface can be configured with various dimensions such as multiple rows and columns, e.g., depending on specific application requirements. As an example, a FIFO cache can be set up as 32 rows by 8 columns (e.g., each row can store 8 data points, where each data point can be a bit, a byte, a word, or a larger unit), allowing a total storage of 256 data points. In some implementations, before outputting data from the memory device to the memory controller, the data are first read from the memory cell array in serial and stored in the FIFO cache.

In some implementations, the frequency divider circuit 604 can include one or more frequency dividers. For example, as shown in FIG. 6, the frequency divider circuit 604 includes a frequency divider 642 that generates a third read clock signal (rd_clk_x2) having half the frequency of the first read clock signal 612, a frequency divider 644 that generates a fourth read clock signal (rd_clk_x4) having one-fourth the frequency of the first read clock signal 612, and a frequency divider 646 that generates a fifth read clock signal (rd_clk_x8) having one-eighth the frequency of the first read clock signal 612.

In some implementations, the read address shifter 606 can receive a first input including an address 662 of the output data 524, and a second input including a quantity of warmup cycles 664 before the data output cycles 514. As an example, the full column address of the output data 524 can include 14 bits represented by CA<13:0>, where CA<13> is the most significant bit and CA<0> is the least significant bit. The memory controller can select memory planes in the memory cell array based on the first ten bits (CA<13: 4>) in the column address, and the I/O interface 416 can select specific memory cells in the selected memory plane using the last four bits (CA<3:0>) in the column address. In some implementations, the address 662 can include the second and third least significant bits (e.g., CA<2:1>) of the full column address of the output data 524.

In some implementations, the quantity of warmup cycles 664 can be represented by wu_do<1: 0> that includes two bits. For example, wu_do<1:0> being “00” indicates that no warmup cycles 512 are provided before the data output cycles 514; wu_do<1:0> being “01” indicates that one warmup cycle 512 is provided before the data output cycles 514; wu_do<1:0> being “10” indicates that two warmup cycles 512 are provided before the data output cycles 514; and wu_do<1:0> being “11” indicates that four warmup cycles 512 are provided before the data output cycles 514.

The read address shifter 606 can output a shifted address 666 based on the address 662 of the output data 524 and the quantity of warmup cycles 664. In some implementations, the shifted address 666 can be determined as the address 662 less the quantity of warmup cycles 664. As such, the shifted address 666 is the address of the warmup data 522 to be read in warmup cycles 512.

In some implementations, the read address shifter 606 can send the shifted address 666 and a control signal 668 to the frequency divider 644. For example, the control signal 668 (e.g., sel_u2b) can be used to choose 2 data points out of 4 data points. The frequency divider 644 can send a control signal (e.g., sel_u4b) and the fourth significant bit (CA<3>) of the column address to the frequency divider 646. For example, the control signal (e.g., sel_u4b) can be used to choose 4 data points out of 8 data points. The frequency divider 646 can send a control signal (e.g., sel_u8b) and a FIFO address (e.g., FIFO<n:0>) to the FIFO cache. For example, the control signal (e.g., sel_u8b) can be used to choose 8 data points out of 16 data points, and the FIFO address can indicate a starting address in the FIFO cache where data output process 500 (including warmup cycles) starts. In some implementations, when reading data from the memory cell array to the FIFO cache before outputting data to the memory controller, data are read in serial in a unit of 16 data points. As such, the frequency divider circuit 604 can be configured to select 2 data points out of the 16 data points, so that each data line of DQ[7:0] of the I/O interface 416 can output 2 data points during a DQS cycle.

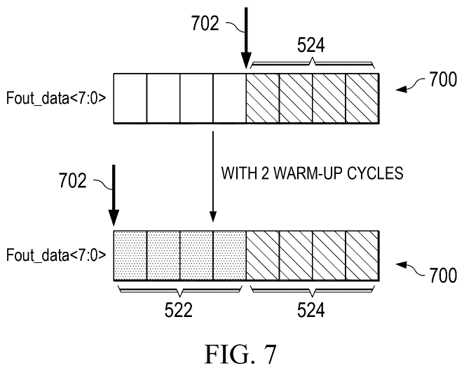

FIG. 7 illustrates a schematic diagram of an example process of generating the shifted address 666 based on the address 662 of the output data 524 and the quantity of warmup cycles 664, according to some aspects of the present disclosure. In some implementations, output data 524 are first stored in a FIFO cache 700, before being output, for example, to a memory controller. As an example, the FIFO cache 700 can be set up as having multiple rows, and each row can store 8 data points. Under the scenario where two data points are read during a DQS cycle (e.g., data are read in response to both the rising edge and the falling edge for DQS), the address 662 (e.g., CA<2:1>) being “00” indicates that the output data 524 starts at the first data point in a row of the FIFO cache 700; CA<2:1> being “01” indicates that the output data 524 starts at the third data point in the row; CA<2:1> being “10” indicates that the output data 524 starts at the fifth data point in the row; and CA<2:1> being “11” indicates that the output data 524 starts at the seventh data point in the row.

The read address shifter 606 can determine the address (e.g., CA<2:1>) 662 less the quantity of warmup cycles (e.g., wu_do<1 0>) as the shifted address 666. As an example shown in FIG. 7, the output data 524 starts at the fifth data point in the row of the FIFO cache 700, for example, CA<2 1> is “10”. When two warmup cycles are included before the data output cycles, (e.g., wu_do<1:0>being “10”), the shifted address 666 (e.g., shifted CA<2:1>) is “00”, that is, the warmup data 522 starts at the first data point in the row of the FIFO cache 700. In some implementations, an output pointer 702 of the FIFO cache 700 can shift to a place indicated by the shifted address 666, so that data output process 500 from the FIFO cache 700 can start at the shifted address 666. As such, when the warmup cycles are completed, the output pointer 702 can point to the address 662 of the output data 524.

In some implementations, the FIFO cache 700 can have a different configuration, and the read address shifter 606 can determined the shifted address in a different manner.

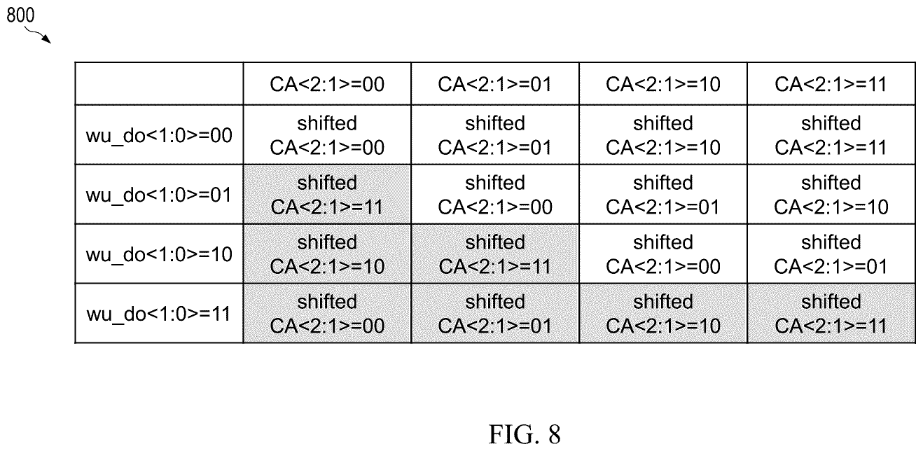

FIG. 8 illustrates an example look-up table 800 of shifted address 666 (e.g., shifted CA<2:1>) based on the address 662 (e.g., CA<2:1>) of the output data 524 and the quantity of warmup cycles 664 (e.g., wu_do<1:0>), according to some aspects of the present disclosure. In some cases, the column address CA<2 1> less the quantity of warmup cycles wu_do<1:0> is a negative value, as indicated by grey cells in the look-up table 800. In such cases, the read address shifter 606 can account for the negative value when determining the shifted address 666. For example, when CA<2:1> is “00” and wu_do<1:0> is “01”, the shifted column address is “11”. That is, the warmup data 522 starts at the seventh data point in the row of the FIFO cache 700. In addition, the read address shifter 606 can send a control signal 668 to the frequency divider 644 that controls the output pointer 702 to stay in the same row. In some implementations, the control signal 668 can instruct the output pointer 702 to skip a first rising edge of the fourth read clock signal (rd_clk_x4) generated by the frequency divider 644. As such, when the output pointer 702 moves to the end of the row of the FIFO cache 700, instead of moving to the beginning of the next row, the output pointer 702 moves to the beginning of the same row. In this way, when the warmup cycles are completed, the output pointer 702 can accurately point to the address 662 of the output data 524.

In some implementations, the frequency divider 644 can include four D flip-flops. The D flip-flops can generate signals that mimic clock signals, which are used to output warmup data 522 during warmup cycles 512. For example, signals generated by each D flip-flop can have the same frequency but different phases. Adjacent D flip-flops can have a phase difference of 90 degrees between each other.

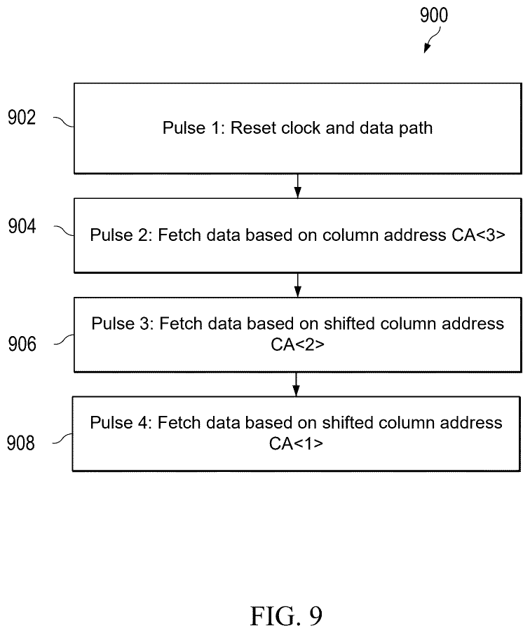

FIG. 9 illustrates a flow chart of an example process 900 of fetching data from an output buffer, according to some aspects of the present disclosure. In some implementations, the I/O interface 416 can use four pulses to fetch data from an output buffer (e.g., the FIFO cache 700 of FIG. 7), before outputting data to a memory controller. The process 900 can support a warmup operation by outputting warmup data 522 during warmup cycles 512 before data output cycles 514.

Before the first pulse, the read address shifter 606 of the I/O interface can generate the shifted address (e.g., shifted CA<2:1>) 666 based on the address 662 (e.g., CA<2:1>) and the quantity of warmup cycles 664 (e.g., wu_do<1:0>). The shifted address 666 can be a start address of warmup data 522 to be read during warmup cycles 512.

At 902, during the first pulse, the I/O interface 416 resets the read clock (e.g., the first read clock signal 612 (rd_clk_x1) of FIG. 6) and resets the data path (e.g., DQ<7:0> of FIG. 5).

At 904, during the second pulse, the I/O interface 416 fetches data (e.g., from the FIFO cache 700) based on the fourth least significant bit (e.g., CA<3>) in the column address. In some implementations, CA<3> can indicate whether to select the first 8 data points or the last 8 data points of given 16 data points in the FIFO cache 700. During the second pulse, the selected 8 data points are fetched.

At 906, during the third pulse, the I/O interface 416 fetches data (e.g., from the FIFO cache 700 or another buffer that stores the fetched 8 data points during the second pulse) based on the third least significant bit (e.g., CA<2>) in the column address after address shifting. In some implementations, CA<2> can indicate whether to select the first 4 data points or the last 4 data points of the selected 8 data points. During the third pulse, the selected 4 data points are fetched.

At 908, during the fourth pulse, the I/O interface 416 fetches data (e.g., from the FIFO cache 700 or another buffer that stores the fetched 4 data points during the third pulse) based on the second least significant bit (e.g., CA<1>) in the column address after address shifting. In some implementations, CA<1> can indicate whether to select the first 2 data points or the last 2 data points of the selected 4 data points. During the third pulse, the selected 2 data points are fetched and ready to be output through a data line of DQ<7:0>.

In some implementations, the process 900 applies to outputting data in response to a read command from the memory controller. In some implementations, the process 900 also applies to resumed data output after a read pause, so that warmup cycles are included before resumed data output. In such cases, before 902, one of a chip enable signal (CE_n), a command latch enable signal (CLE), or an address latch enable signal (ALE) is set to high to indicate the read pause. The read address shifter 606 can calculate the shifted address for warmup data at the beginning of the resumed data output, e.g., based on the address of data to be resumed read, and the quantity of warmup cycles. Similarly, the I/O interface 416 can use four pulses (e.g., as described with reference to 902, 904, 906 and 908) to fetch data from the output buffer, so that warmup data are output at the beginning of the resumed data output.

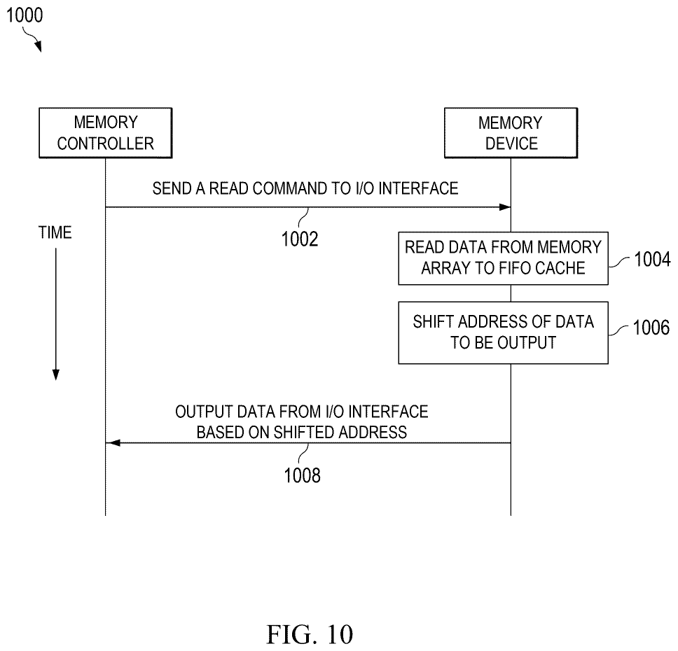

FIG. 10 illustrates an example method 1000 of reading data from a memory system (e.g., the memory system 102 of FIG. 1), according to some aspects of the present disclosure. The method 1000 can be performed according to the example techniques described with respect to FIGS. 1-9. The memory system can include a memory controller (e.g., memory controller 106 of FIG. 1) and a memory device (e.g., memory device 104 of FIG. 1). The memory device can include a memory cell array (e.g., memory cell array 301 of FIG. 3) an I/O interface (e.g., I/O interface 416 of FIGS. 4 and 6).

At 1002, the memory controller sends a read command to the I/O interface of the memory device. The read command can include a first address (e.g., column address 662) of data to be read in response to the read command.

At 1004, to increase the speed of data transmission, data are first read from the memory cell array to a FIFO cache (e.g., the FIFO cache 700 of FIG. 7) of the I/O interface, before being output to the memory controller from the I/O interface.

At 1006, a read address shifter (e.g., the read address shifter 606 of FIG. 6) of the I/O interface shifts the first address to a second address. In some implementations, the read address shifter can receive inputs including the first address, and a quantity of warmup cycles before data output cycles. The read address shifter can calculate the second address as the first address less the quantity of warmup cycles. As such, the second address can be the starting address of warmup data (e.g., warmup data 522 of FIG. 4 and FIG. 7) that are output during warmup cycles. In some implementations, in response to determining that the first address less the quantity of warmup cycles is a negative value (e.g., as shown in FIG. 8), the read address shifter can account for the negative value in determining the second address.

At 1008, the memory device sends data from the I/O interface to the memory controller. In some implementations, the I/O interface can fetch data from the FIFO cache using four pulses as shown in FIG. 9. Since the read address shifter has shifted the first address to the second address, the data lines DQ[7:0] first output warmup data starting at the second address during the warmup cycles, and then outputs data starting at the first address. In some implementations, the data starting at the first address are sent to the memory controller via the I/O interface.

The operations shown in method 1000 may not be exhaustive and that other operations can be performed as well before, after, or in between any of the illustrated operations. Further, some of the operations may be performed simultaneously, or in a different order than shown in FIG. 10. In some implementations, some of the operations may be performed by or one or more components of a device or a system, such as, a peripheral circuit of the memory device.

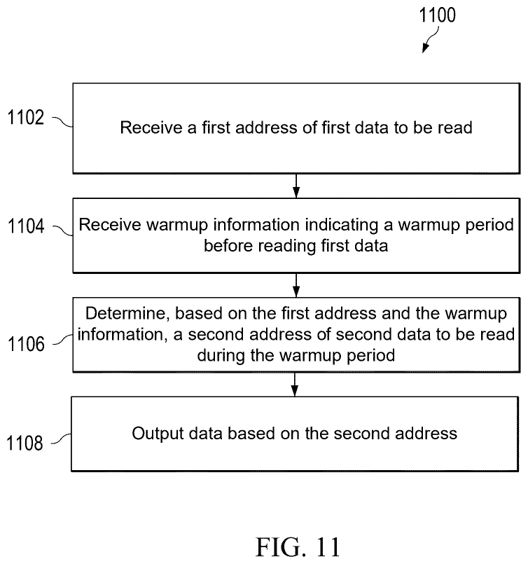

FIG. 11 illustrates a flow chart of an example process 1100 of performing a read operation that includes warmup cycles (e.g., warmup cycles 512 before data output cycles 514 of FIG. 5), according to some aspects of the present disclosure. Process 1100 can be performed by any suitable device or system as described herein, for example, according to the example techniques described with respect to FIGS. 1-10. For example, process 1100 can be performed by a memory device (e.g., the memory device 104 of FIGS. 1-2B, or the memory device 300 of FIG. 3 that includes a memory cell array 301), by an I/O interface of the memory device (e.g., the I/O interface 416 of FIG. 4 and FIG. 6), or by a memory system (e.g., the memory system 102 of FIG. 1).

At 1102, a first address (e.g., the address 662) of first data (e.g., output data 524 of FIG. 5 and FIG. 7) to be read during the read operation is received. In some implementations, the first address can include the second and third least significant bits (e.g., CA<2:1>) of the full column address (e.g., CA<13:0>) of the first data.

At 1104, warmup information is received. Warmup information can include warmup configuration information indicating a warmup period (e.g., including warmup cycles 512 of FIG. 5) before reading the first data. In some implementations, the warmup period can include a quantity of warmup cycles (e.g., one, two or four warmup cycles) before reading the first data.

At 1106, a second address (e.g., shifted address 666 of FIG. 6) of second data (e.g., warmup data 522 of FIG. 5 and FIG. 7) to be read during the warmup period can be determined based on the first address and a quantity of warmup cycles (e.g., the quantity of warmup cycles 664 of FIG. 6) in the warmup period. In some implementations, the second address can be determined as the first address less the quantity of warmup cycles, for example, as shown in look-up table 800 of FIG. 8.

In some implementations, the second address is received by a first frequency divider (e.g., frequency divider 644 of FIG. 6) of a frequency divider circuit (e.g., the frequency divider circuit 604 of FIG. 6). The first frequency divider can generate, based on a first clock signal (e.g., the first read clock signal (rd_clk_x1)), a second clock signal (e.g., the fourth read clock signal (rd_clk_x4)) having one-fourth a frequency of the first clock signal. In some implementations, in response to determining that the first address less the quantity of warmup cycles is a negative value (e.g., as shown in grey cells in look-up table 800), the second address is determined by accounting for the negative value. For example, an address shifter (e.g., the read address shifter 606 of FIG. 6) can sending a control signal (e.g., control signal 668 of FIG. 6) to the first frequency divider. The control signal is configured to instruct an output pointer (e.g., the output pointer 702 of FIG. 7) of a FIFO cache (e.g., the FIFO cache 700 of FIG. 7) to skip a first rising edge of the second clock signal during the warmup period.

At 1108, data are read or output, e.g., through DQ<7:0> starting from the second address. As shown in FIG. 5, in response to RE_n signals and corresponding DQS signals, the second data are read out during the warmup cycles 512, starting from the second address. After the warmup cycles, the first data are read out during data output cycles 514, starting from the first address. As such, since warmup cycles are provided before outputting the first data, data integrity and accuracy are enhanced when outputting the first data. In some implementations, one or both of the first data or the second data are sent out, for example, from a memory device to a memory controller via an I/O interface.

The operations shown in process 1100 may not be exhaustive and that other operations can be performed as well before, after, or in between any of the illustrated operations. Further, some of the operations may be performed simultaneously, or in a different order than shown in FIG. 11. In some implementations, some of the operations may be performed by or one or more components of a device or a system, such as, a peripheral circuit of the memory device.

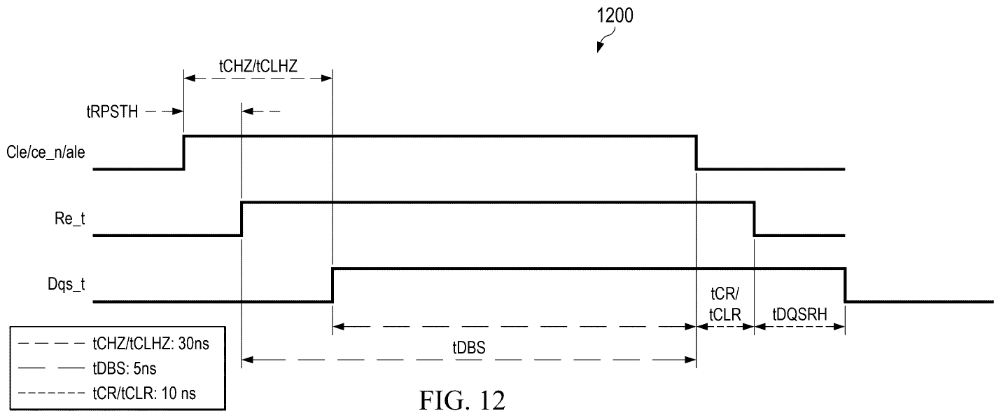

FIG. 12 illustrates a schematic timing diagram 1200 of example read pause and resume, according to some aspects of the present disclosure. The timing diagram 1200 includes signals such a chip enable signal (CE_n), a command latch enable signal (CLE), an address latch enable signal (ALE), a read enable signal (RE_t) and a data strobe signal (DQS_t). To indicate the read pause, one of CE_n, CLE or ALE can be held high for longer than a threshold duration (e.g., 1 us). According to Open NAND flash Interface (ONFi) Specification, a time duration for resuming data output after the read pause should be less than 45 ns. Specifically, the time duration for resuming data output should be less than a sum of (1) tCHZ (time for CE_n being high to output Hi-Z) or tCLHZ (time for CLE being high to output Hi-Z), which can last a maximum of 30 ns, (2) tBDS (time for DQS_t being high and RE_t being high so as to set ALE, CLE or CE_n to low), which can last a maximum of 5 ns, and (3) tCR (time delay between CE_n is set low and RE_t is set low) or tCLR (time delay between CLE is set low to RE_t is set low), which can last a maximum of 10 ns.

In some implementations, warmup cycles are provided at the beginning of resumed data output. The I/O interface can use the four pulses as illustrated in FIG. 9 to fetch data from an output buffer (e.g., the FIFO cache 700 of FIG. 7) before resuming to output data, so that the data lines DQ[7:0] can first output warmup data during the warmup cycles. In some implementations, by including the four pulse at the beginning of the resumed data output, the time duration for resuming data output is still under 45 ns, thereby conforming to relevant protocols in the ONFi Specification.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. An input/output (I/O) interface of a memory device, configured to:
receive a first address of first data to be read;
receive warmup information that indicates a warmup period before reading the first data; and
determine, based on the first address and the warmup information, a second address of second data to be read during the warmup period before reading the first data.

2. The I/O interface of claim 1, wherein the I/O interface comprises an address shifter and a first frequency divider coupled to the address shifter, wherein the address shifter is configured to:
determine the first address less a quantity of warmup cycles as the second address; and
send the second address to the first frequency divider.

3. The I/O interface of claim 2, wherein the address shifter is configured to:
in response to determining that the first address less the quantity of warmup cycles is a negative value, account for the negative value in determining the second address.

4. The I/O interface of claim 3, wherein the I/O interface receives a first clock signal, and wherein the first frequency divider is configured to generate a second clock signal having one-fourth a frequency of the first clock signal.

5. The I/O interface of claim 4, wherein the first data and the second data are read from a first-in-first-out (FIFO) cache of the memory device.

6. The I/O interface of claim 5, wherein the address shifter is configured to account for the negative value in determining the second address by sending a control signal to the first frequency divider, wherein the control signal is configured to instruct an output pointer of the FIFO cache to skip a first rising edge of the second clock signal during the warmup period.

7. The I/O interface of claim 4, comprising:
a second frequency divider configured to generate a third clock signal having half the frequency of the first clock signal; and
a third frequency divider configured to generate a fourth clock signal having one-eighth the frequency of the first clock signal.

8. The I/O interface of claim 1, configured to:
in response to receiving a read command to read the first data:
reset a data path of the I/O interface during a first pulse;
read data based on a fourth least significant bit of the second address during a second pulse;
read data based on a third least significant bit of the second address during a third pulse; and
read data based on a second least significant bit of the second address during a fourth pulse.

9. The I/O interface of claim 1, configured to:
in response to receiving, after a read pause, a read resume command to read the first data:
reset a data path of the I/O interface during a first pulse;
read data based on a fourth least significant bit of the second address during a second pulse;
read data based on a third least significant bit of the second address during a third pulse; and
read data based on a second least significant bit of the second address during a fourth pulse.

10. The I/O interface of claim 1, configured to:
output the second data during the warmup period; and
output the first data after the warmup period.

11. A memory device, comprising:
a memory cell array comprising memory cells; and
peripheral circuits coupled to the memory cell array, wherein the peripheral circuits comprise an input/output (I/O) interface configured to:
receive a first address of first data to be read;
receive warmup information that indicates a warmup period before reading the first data; and
determine, based on the first address and the warmup information, a second address of second data to be read during the warmup period before reading the first data.

12. The memory device of claim 11, wherein the I/O interface comprises an address shifter and a first frequency divider coupled to the address shifter, wherein the address shifter is configured to:
determine the first address less a quantity of warmup cycles as the second address; and
send the second address to the first frequency divider.

13. The memory device of claim 12, wherein the address shifter is configured to:
in response to determining that the first address less the quantity of warmup cycles is a negative value, account for the negative value in determining the second address.

14. The memory device of claim 13, wherein the peripheral circuits comprise a first-in-first-out (FIFO) cache, and wherein the first data and the second data are read from the FIFO cache.

15. The memory device of claim 14, wherein the I/O interface receives a first clock signal,
wherein the first frequency divider is configured to generate a second clock signal having one-fourth a frequency of the first clock signal,
wherein the address shifter is configured to account for the negative value in determining the second address by sending a control signal to the first frequency divider, and
wherein the control signal is configured to instruct an output pointer of the FIFO cache to skip a first rising edge of the second clock signal during the warmup period.

16. The memory device of claim 11, wherein the peripheral circuits are configured to:
read the second data during the warmup period; and
read the first data after the warmup period.

17. The memory device of claim 1, wherein the memory device comprises a NAND memory device.

18. A memory system, comprising:
a memory controller configured to send a read command to read first data, a first address of the first data and warmup information that indicates a warmup period before reading the first data; and
a memory device coupled to the memory controller, the memory device comprising:
a memory cell array comprising memory cells; and
a peripheral circuit comprising an input/output (I/O) interface configured to:
receive the read command, the first address and the warmup information; and
determine, based on the first address and the warmup information, a second address of second data to be read during the warmup period before reading the first data.

19. The memory system of claim 18, wherein determining the second address comprises:
determining the first address less a quantity of warmup cycles as the second address.

20. The memory system of claim 18, wherein the peripheral circuit is configured to:
read the second data during the warmup period; and
read the first data array after the warmup period.
